(19) United States
(12) Patent Application Publication
(10) Pub. No.: US 2009/0278241 A1
(43) Pub. Date: Nov. 12, 2009

(54) SEMICONDUCTOR DIE PACKAGE INCLUDING DIE STACKED ON PREMOLDED SUBSTRATE INCLUDING DIE

(76) Inventors: Yong Liu, Scarborough, ME (US); Yumin Liu, Suzhou (CN); Duane Sorlie, Escondido, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/117,547

(22) Filed: May 8, 2008

(51) Int. Cl. H01L 23/495; H01L 21/60

(52) U.S. Cl. 257/676; 438/109; 257/E23.037; 257/E21.51

(57) ABSTRACT

A semiconductor die package. The semiconductor includes a premolded substrate. The premolded substrate includes (i) a leadframe structure, (ii) a first semiconductor die comprising a first die surface and a second die surface, attached to the leadframe structure, and (iii) a molding material covering at least a portion of the leadframe structure and the first semiconductor die. The premolded substrate includes a first premolded substrate surface and a second premolded substrate surface. A second semiconductor die is stacked on the second premolded substrate surface of the premolded substrate. A housing material is on at least a portion of the second semiconductor die and the second premolded substrate surface of the premolded substrate. One of the first semiconductor die and the second semiconductor die includes a transistor while the other includes an integrated circuit.

### CROSS REFERENCE TO RELATED APPLICATIONS

This application is related to U.S. patent application Ser. No. 12/047,028 entitled “Semiconductor Die Package Including Embedded Flip Chip,” which was filed on Mar. 12, 2008, U.S. patent application Ser. No. 12/046,939, entitled “Semiconductor Die Package Including Multiple Semiconductor Dies,” which was filed on Mar. 12, 2008, and U.S. patent application Ser. No. 11/971,556, entitled “Die Package Including Substrate With Molded Device” filed on Jan. 9, 2008, all of which are herein incorporated by reference in their entirety for all purposes.

### BACKGROUND

Portable devices such as cell phones are proliferating. There is consequently a need for smaller semiconductor die packages with better heat dissipation properties.

One particular area where a small semiconductor die package would be useful is in a circuit, which provides over-voltage protection (OVP) for a connection that includes D+/D− lines. One company, On Semi, produces a semiconductor die package which includes this function (a Vbus OVP function). However, it is a dual co-planar dice package. It does not have a D+/D− connectivity detection function in a dual dice package as in embodiments of the invention.

Another problem to be solved is to provide for the ability to dissipate heat from a semiconductor die comprising a power transistor in a semiconductor die package including multiple dice. For example, if a power transistor die and an integrated circuit die are stacked on top of each other within a semiconductor die package, heat from the power transistor die can pass directly to the integrated circuit die, thus increasing the chance that the integrated circuit die might fail.

Embodiments of the invention address the above problems and other problems individually and collectively.

### BRIEF SUMMARY

Embodiments of the invention are directed to semiconductor die packages and methods for making the same.

One embodiment of the invention is directed to a semiconductor die package. The semiconductor die package includes a premolded substrate comprising (i) a leadframe structure, (ii) a first semiconductor die comprising a first die surface and a second die surface, attached to the leadframe structure, and (iii) a molding material covering at least a portion of the leadframe structure and the first semiconductor die. The premolded substrate comprises a first premolded substrate surface and a second premolded substrate surface. A second semiconductor die is stacked on the second premolded substrate surface. A housing material is formed on at least a portion of the second semiconductor die and the second premolded substrate surface. One of the first semiconductor die and the second semiconductor die comprises a transistor while the other comprises an integrated circuit.

Another embodiment of the invention is directed to a method forming a premolded substrate comprising (i) a leadframe structure, (ii) a first semiconductor die comprising a first die surface and a second die surface, attached to the leadframe structure, and (iii) a molding material covering at least a portion of the leadframe structure and the first semiconductor die. The premolded substrate comprises a first premolded substrate surface and a second premolded substrate surface. After the premolded substrate is formed, a second semiconductor die is stacked on the second premolded substrate surface. After the second semiconductor die is stacked on the second premolded substrate surface, a housing material is formed on at least a portion of the second semiconductor die and the second premolded substrate surface. A semiconductor die package is thereafter formed. In the semiconductor die package, one of the first semiconductor die and the second semiconductor die comprises a transistor, while the other comprises an integrated circuit.

These and other embodiments of the invention are described in further detail in the Detailed Description with reference to the Figures.

### BRIEF DESCRIPTION OF THE DRAWINGS

FIG. 1 shows a top perspective view of a semiconductor die package according to an embodiment of the invention.

FIG. 2 shows a bottom perspective view of the semiconductor die package embodiment shown in FIG. 1.

FIG. 3 shows a top perspective view of the semiconductor die package embodiment shown in FIG. 1, with components inside of the package being shown.

FIG. 4 shows a bottom perspective view of the semiconductor die package embodiment shown in FIG. 1, with components inside of the package being shown.

FIGS. 5(a)-5(d) respectively show top, bottom, and two side views of a semiconductor die package, with internal components being shown.

FIGS. 6(a)-6(g) show precursors that are formed during the formation of a semiconductor die package according to an embodiment of the invention.

FIG. 7 shows a top perspective view of another semiconductor die package embodiment.

FIG. 8 shows a bottom perspective view of the semiconductor die package embodiment shown in FIG. 7.

FIGS. 9 shows a top perspective view of the semiconductor die package embodiment in FIG. 7 with internal components being shown.

FIGS. 10(a)-10(d) respectively show top, bottom, and two side views of the semiconductor die package embodiment shown in FIG. 7, with internal components being shown.

FIGS. 11(a)-11(g) show precursors that are formed during the formation of a semiconductor die package according to an embodiment of the invention.

FIGS. 12-13 show circuit diagrams.

In the Figures, like numerals may designate like elements and the descriptions of elements may not be repeated.

### DETAILED DESCRIPTION

A number of embodiments of the invention are described herein. Embodiments of the invention include methods for electrically interconnecting an IC (integrated circuit) die and a MOSFET (metal oxide semiconductor field effect transistor) die through a premolded substrate comprising a leadframe structure and the MOSFET die. Embodiments of the invention may also include a method for designing a premolded leadless package (MLP) with patterned I/Os (input/outputs). Embodiments of the invention may also include a method for designing a semiconductor die package with an exposed die surface to achieve better electrical and thermal performance. For example, an exposed MOSFET drain surface in the semiconductor die package can provide an electrical connect pin (Vₒᵤₜ) and a more direct thermal path to the outside environment (e.g., to a circuit board). Embodiments of the invention may also include methods for offsetting an integrated circuit die with respect to a MOSFET die. This shrinks the size of a semiconductor die package and prevents heat that is generated from the MOSFET die from passing directly to the integrated circuit die. Embodiments of the invention may also include a method of assembly, which places a flip chip MOSFET on a leadframe structure (or a MOSFET die which can be wirebonded to the leads in the premolded substrate) in a semiconductor die package. Embodiments of the invention may also include methods for attaching an integrated circuit die to a premolded substrate.

Some embodiments of the invention allow for a 3D (three-dimensional) stacked multiple dice package switch for a cell phone system level application which combines an integrated circuit die and a p-channel MOSFET die in a single semiconductor die package. Embodiments of the invention can provide a power protection function for a V_{bus} pin for over voltage protection. The formed package may have a standard industry pin out.

One embodiment of the invention is directed to a semiconductor die package.

The semiconductor die package includes a premolded substrate comprising (i) a leadframe structure, (ii) a first semiconductor die comprising a first die surface and a second die surface, attached to the leadframe structure, and (iii) a molding material, such as an epoxy based molding material or some other suitable molding material, covering at least a portion of the leadframe structure and the first semiconductor die. The premolded substrate comprises a first premolded substrate surface and a second premolded substrate surface. A second semiconductor die is stacked to the second premolded substrate surface. A housing material is formed on at least a portion of the second semiconductor die and the second premolded substrate surface of the premolded substrate. One of the first semiconductor die and the second semiconductor die comprises a transistor while the other comprises an integrated circuit.

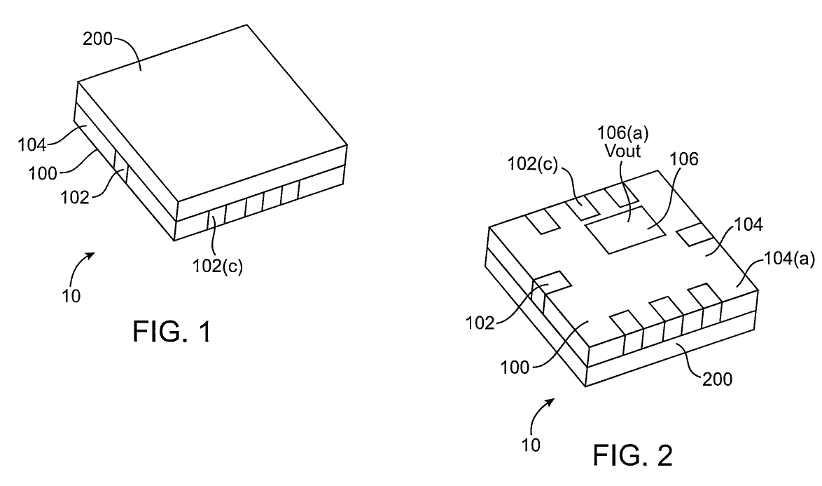

FIG. 1 shows a top perspective view of a semiconductor die package 10 according to an embodiment of the invention. The semiconductor die package 10 comprises a premolded substrate 100 and a housing material 200 on the premolded substrate 100. The premolded substrate 100 comprises a molding material 104 and a leadframe structure 102.

The semiconductor die package 10 can comprise a length L (e.g., about 2.5 mm), a width W (e.g., about 1.5 mm), and a height H (e.g., 0.7 mm). As shown, the semiconductor die package 10 comprises a molding material 104 covering the leadframe structure 102. The leadframe structure 102 comprises leads 102(c). The side surfaces of the leads 102(c) of the leadframe structure 102 are shown as being part of the side walls of the semiconductor die package 10. The leads 102(c) do not extend past lateral surfaces of the housing material 200 and the molding material 104. In some instances, the semiconductor die package 10 may be characterized as a “leadless” semiconductor die package, since leads do not extend laterally outward from the housing material 200 and the molding material 104 in the premolded substrate 100.

FIG. 2 shows a bottom perspective view of the semiconductor die package 10 shown in FIG. 1. In addition to showing a leadframe structure 102 and a molding material 104, a first die surface 106(a) of a first semiconductor die 106 is shown. The first die surface 106(a) may correspond to a drain terminal in a MOSFET in the first semiconductor die 106, and may be substantially coplanar with an exterior surface 104(a) of the molding material 104. The exterior surface 104(a) of the molding material 104 may coincide with the bottom exterior surface of the semiconductor die package 10. Leads 102(c) in the leadframe structure 102 may surround the first die surface 106(a).

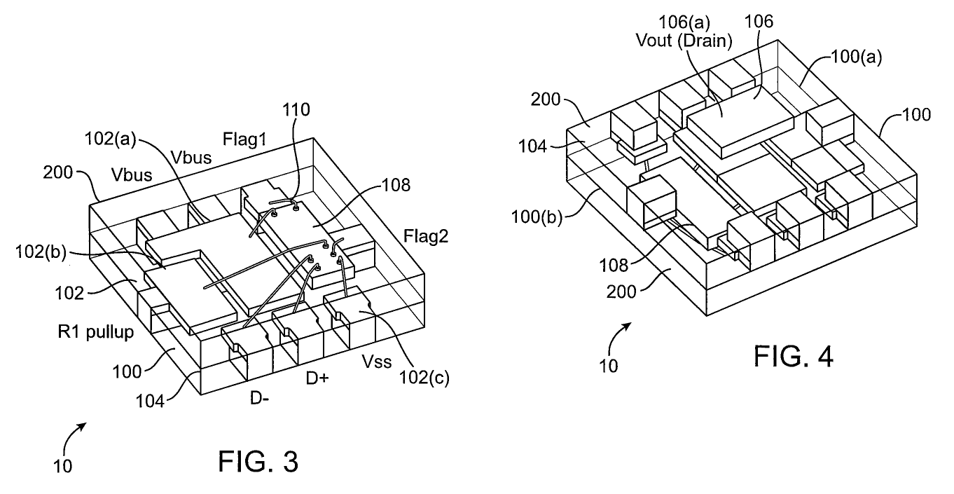

FIG. 3 shows a top perspective view of the semiconductor die package 10 shown in FIG. 1. Internal components inside of the semiconductor die package 10 are shown.

As shown, the leadframe structure 102 comprises a first die attach pad portion 102(a) and a second die attach pad portion 102(b), which are physically and electrically separated from each other. In the semiconductor die package 10, the first die attach pad portion 102(a) may electrically couple to a source region in a MOSFET in the first semiconductor die 106. The second die attach pad portion 102(b) may electrically couple to a gate region in the MOSFET in the first semiconductor die. Solder, a conductive epoxy, etc. may be used to electrically and mechanically couple the first semiconductor die 102 to the die attach pad portions 102(a), 102(b) of the leadframe structure 102. As will be described in detail below, surfaces of the first die attach pad portion 102(a) and the second die attach pad portion 102(b) that are opposite to the die attach surfaces may be exposed through the molding material 104 and may be substantially coplanar with an exterior surface of the molding material 104. These surfaces may form a premolded substrate surface, which in turn can be covered with the housing material 200.

Leads 102(c) extend around the first and second die attach pad portions 102(a), 102(b). In this specific embodiment, the leads 102(c) can be designated as follows: Vbus (power input from charger, USB device, or handheld battery), D− (USB data input), D+ (USB data input), R1 (or alternatively LS ctrl or load switch control), Vss (device ground), Flag2 (over/under voltage flag), and Flag 1 (charger/USB device detect flag). The leads 102(c) can additionally or alternatively form thermal paths to the outside environment.

As shown in FIG. 2, the die surface 106(a) may form a Vout (output voltage) connection for the semiconductor die package 10 so that a separate lead for Vout is not needed. This saves a lead so that the saved lead can advantageously be used for some other function. The exposed die surface 106(a) also provides a direct thermal path to the outside environment.

In FIG. 3, a second semiconductor die 108, which may be an integrated circuit die, is mounted on the premolded substrate 100. The second semiconductor die 108 may be mounted to the molding material 104 in the premolded substrate 100 using a conductive adhesive or a non-conductive adhesive such as solder, or a conductive or non-conductive epoxy material.

The first semiconductor die 106 may include a power transistor, which may be a vertical or horizontal device. Vertical devices have at least an input at one side of the die and an output at the other side of the die so that current can flow vertically through the die. Horizontal devices include at least one input at one side of the die and at least one output at the same side of the die so that current flows horizontally through the die. Exemplary vertical power devices are also described in U.S. Pat. Nos. 6,274,905 and 6,351,018, both of which are assigned to the same assignee as the present application, and both of which are herein incorporated by reference in their entirety for all purposes.

Vertical power transistors include VDMOS transistors and vertical bipolar transistors. A VDMOS transistor is a MOSFET that has two or more semiconductor regions formed by diffusion. It has a source region, a drain region, and a gate. The device is vertical in that the source region and the drain region are at opposite surfaces of the semiconductor die. The gate may be a trenched gate structure or a planar gate structure, and is formed at the same surface as the source region. Trenched gate structures are preferred, since trenched gate structures are narrower and occupy less space than planar gate structures. During operation, the current flow from the source region to the drain region in a VDMOS device is substantially perpendicular to the die surfaces.

In some embodiments, the first semiconductor die 106 may be a semiconductor die with a discrete device such a power MOSFET. For example, the first semiconductor die 106 may be a P-channel MOSFET die that is commercially available from Fairchild Semiconductor Corp.

The second semiconductor die 108 may comprise an integrated circuit die. An integrated circuit die comprises many electrical devices within the die, and may be configured to perform control or detection functions. For example, the integrated circuit die may be configured to detect the presence of a USB device or a battery charger. An integrated circuit die can be compared to a die with only one discrete device. Various types of integrated circuit dice are known.

Wires 110 are formed between the terminals in the second semiconductor die 108 and the leads 102(c) in the leadframe structure 102. The wires 110 may comprise gold, copper, or any other suitable conductive material.

A housing material 200 may cover the second semiconductor die 108 as well as the wires 110. The housing material 200 may comprise a material (e.g., an epoxy material) that is the same or different than the previously described molding material 104. However, since the housing material 200 and the previously described molding material 104 are formed at separate times, there can be an interface between the molding material 104 and the housing material 200. The housing material 200 may cover only one major premolded substrate surface of the premolded substrate 100.

FIG. 4 shows a bottom perspective view of the semiconductor die package 10 shown in FIG. 4. As shown, the first semiconductor die 106 is on the opposite side of the leadframe structure 102 as the second semiconductor die 108. The first semiconductor die 106 is laterally and vertically offset with respect to the second semiconductor die 108. The first die surface 106(a) of the first semiconductor die 106 is exposed through the molding material 104, and is substantially coplanar with an exterior surface of the molding material 104. This minimizes the thickness of the semiconductor die package 10. In addition, FIG. 4 shows a first premolded substrate surface 100(a) and an opposite second premolded substrate surface 100(b). The first and second premolded substrate surfaces 100(a), 100(b) can constitute opposing major surfaces of the premolded substrate 100.

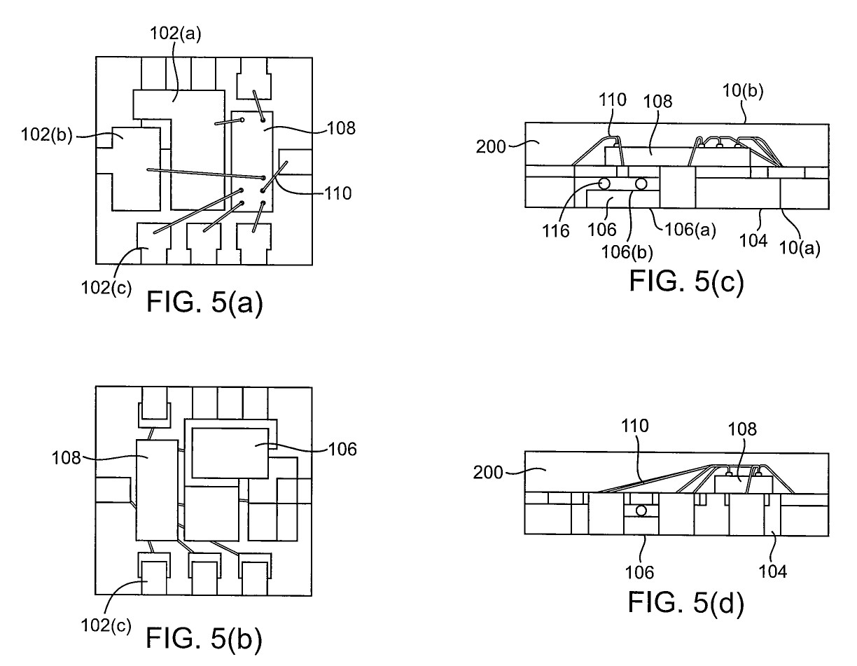

FIGS. 5(a)-5(d) respectively show top, bottom, and two side views of a semiconductor die package. As shown in FIG. 5(c), the first semiconductor die 106 may be coupled to the leadframe structure 102 using solder balls 116 or any other suitable conductive material. FIG. 5(c) also shows a first surface 10(a) of the semiconductor die package 10 and an opposite second surface 10(b) of the semiconductor die package 10.

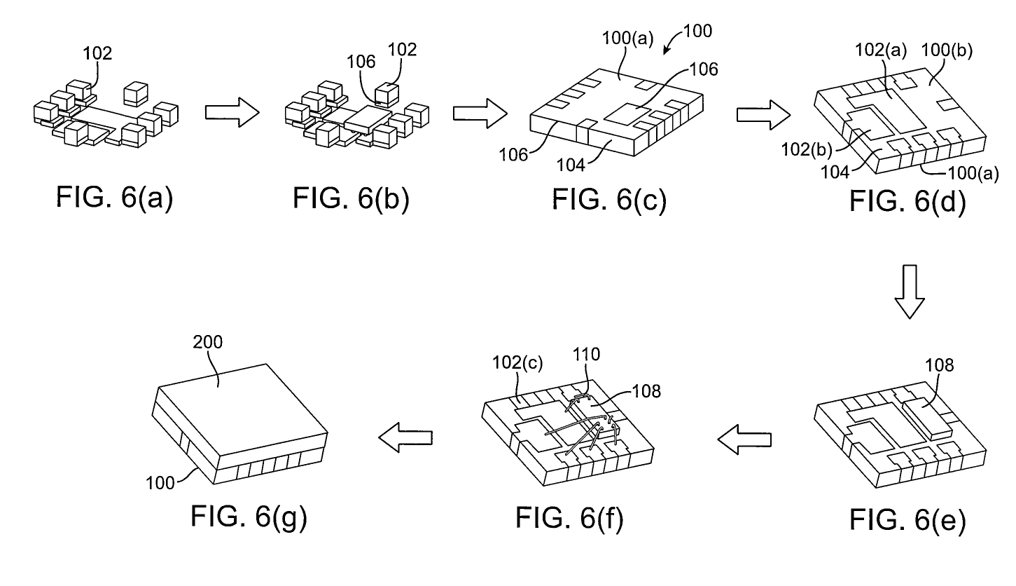

FIGS. 6(a)-6(g) show precursors that are formed during the formation of a semiconductor die package according to an embodiment of the invention.

FIG. 6(a) shows a leadframe structure 102. It may be obtained in any suitable manner. For example, it may be manufactured, as explained below, or it may be otherwise obtained from a commercial source.

The term “leadframe structure” can refer to a structure that is derived from or is the same as a leadframe. Each leadframe structure can include two or more leads with lead surfaces and a die attach region. The leads extend laterally from the die attach region. A single lead frame structure may include a gate lead structure, and a source lead structure.

The leadframe structure 102 may comprise any suitable material. Exemplary leadframe structure materials include metals such as copper, aluminum, gold, etc., and alloys thereof. The leadframe structures may also include plated layers such as plated layers of gold, chromium, silver, palladium, nickel, etc. The leadframe structure may also have any suitable thickness, including a thickness less than about 1 mm (e.g., less than about 0.5 mm).

The leadframe structure can be etched and/or patterned using conventional processes to shape the leads or other portions of the leadframe structure. For example, the leadframe structure can be formed by etching a continuous conductive sheet to form a predetermined pattern. Before or after etching, the leadframe structure can also optionally be stamped so that a die attach surface of the leadframe structure is downset with respect to the lead surfaces of the leads of the leadframe structure. If stamping is used, the leadframe structure may be one of many leadframe structures in an array of leadframe structures that are connected by tie-bars. The leadframe structure array may also be cut to separate the leadframe structures from other leadframe structures. As a result of cutting, portions of a leadframe structure in a final semiconductor die package such as a source lead and a gate lead may be electrically and mechanically uncoupled from each other. Thus, a leadframe structure may be a continuous metallic structure or a discontinuous metallic structure.

Referring to FIG. 6(b), after the leadframe structure 102 is obtained, the first semiconductor die 106 is mounted to the leadframe structure 102 using solder or some other conductive material.

Referring to FIG. 6(c), after the first semiconductor die 106 is mounted to the leadframe structure 102, a molding material 104 may be formed over at least a portion of the leadframe structure 102, and the first semiconductor die 106 to form a premolded substrate 100. As illustrated, the premolded substrate 100 includes a first premolded substrate surface 100(a) and an opposite second premolded substrate surface 100(b) as shown in FIG. 6(d). As shown in FIG. 6(d), the premolded substrate 100 is turned over. The premolded substrate 100 may be formed using a conventional mold tool with molding dies, or may be formed using a conventional tape assisted molding process.

As shown in FIG. 6(e), after the premolded substrate 100 is turned over, the second semiconductor die 108 can be stacked and attached to a non-conductive region of the premolded substrate 100 using an adhesive material (e.g., solder).

As shown in FIG. 6(f), after attaching the second semiconductor die 108 to the premolded substrate 100, wires 110 can be attached to the second semiconductor die 108 and the leads 102(c) of the leadframe structure 102 in the premolded substrate 100 in a wirebonding process. Conventional wirebonding processes may be used.

As shown in FIG. 6(g), after performing the wirebonding process, the housing material 200 may be formed over the premolded substrate 100. The housing material 200 may be formed using a conventional molding process. After the housing material 200 is formed, a singulation process may be performed.

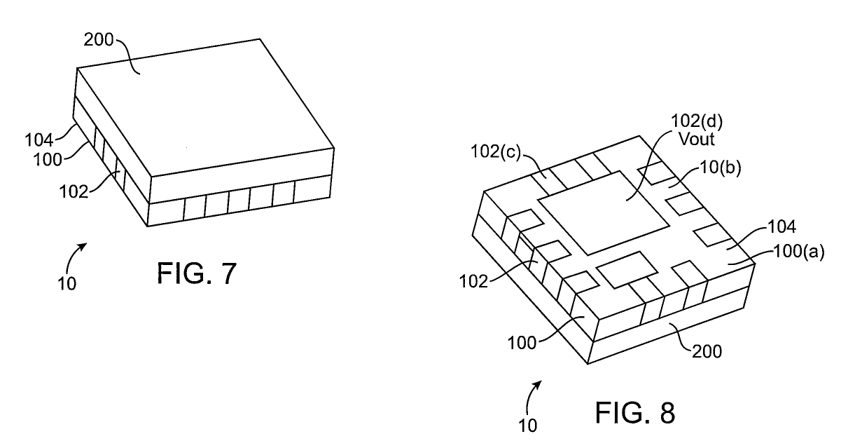

FIG. 7 shows a top perspective view of another semiconductor die package embodiment. The reference numerals in FIG. 7 are the same as those in FIG. 1, and the same descriptions apply with respect to the embodiment in FIG. 7.

FIG. 8 shows a bottom perspective view of the semiconductor die package embodiment shown in FIG. 7. The reference numerals in FIG. 8 are the same as those in FIG. 1, and the same descriptions apply with respect to the embodiment in FIG. 8. However, FIG. 8 additionally shows a pad 102(d) that is part of the leadframe structure 102. The pad 102(d) has an exterior surface that is exposed through the molding material 104 (instead of a die surface as in FIG. 2).

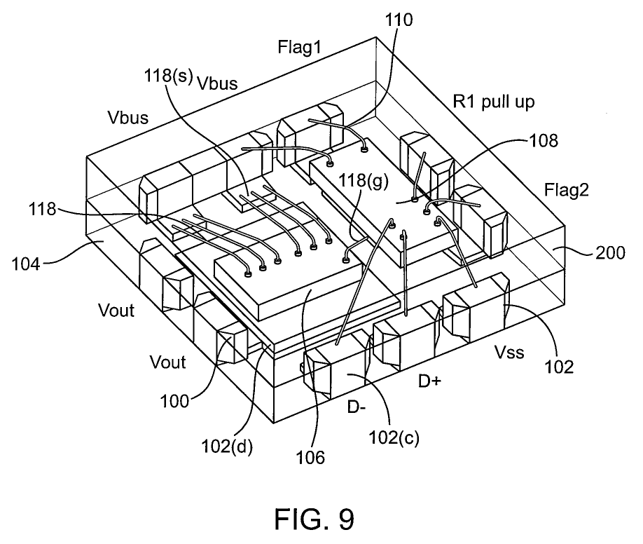

FIGS. 9 shows a top perspective view of the semiconductor die package embodiment in FIG. 7 with internal components being shown. As shown in FIG. 9, the first semiconductor die 106 is at the same side of the leadframe structure 102 as the second semiconductor die 108. It is also mounted on the pad 102(d). The first and second semiconductor dice 106, 108 are laterally and vertically offset with respect to teach other. As shown, the first semiconductor die 106 may comprise a power MOSFET and heat generated from it does not pass directly to the second semiconductor die 108.

Wires 118 couple the source and gate terminals in the first semiconductor die 106 with the leads 102(c) in the leadframe structure 102. The wires 118 include source wires 118(s). A gate wire 118(g) may couple the second semiconductor die 108 to a gate terminal in the first semiconductor die 106.

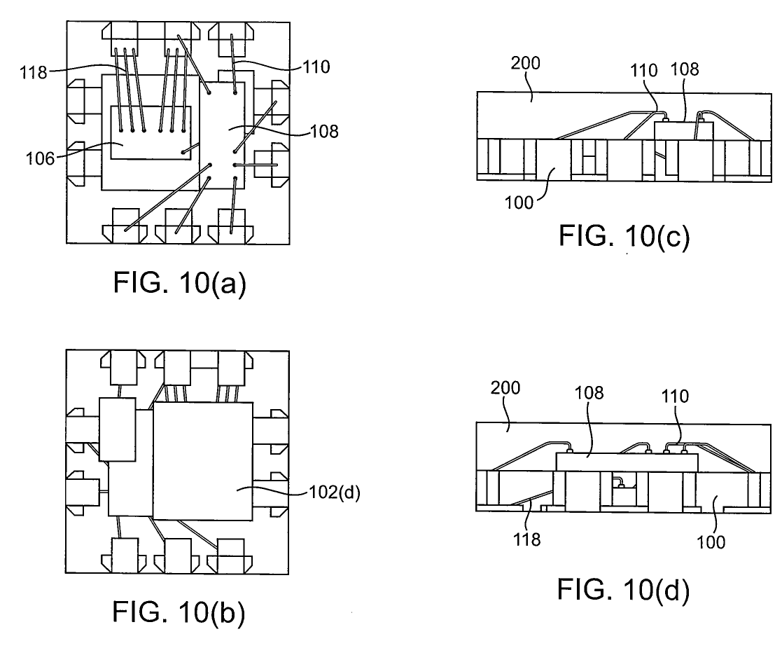

FIGS. 10(a)-10(d) respectively show top, button, and two side views of the semiconductor die package in FIG. 7. As shown in FIGS. 10(c) and 10(d), the semiconductor die package is thin and there is advantageously no semiconductor die that is above or below the first semiconductor die 106.

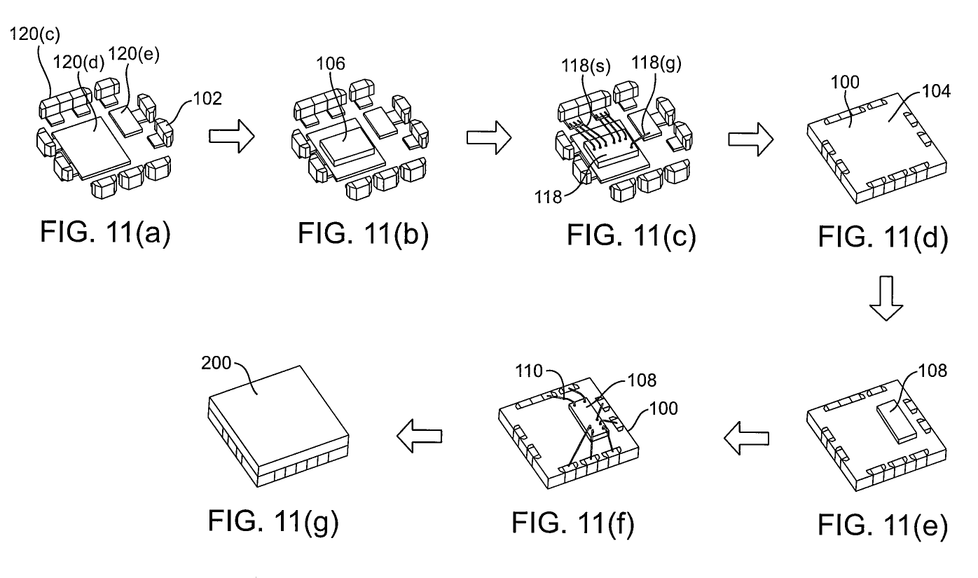

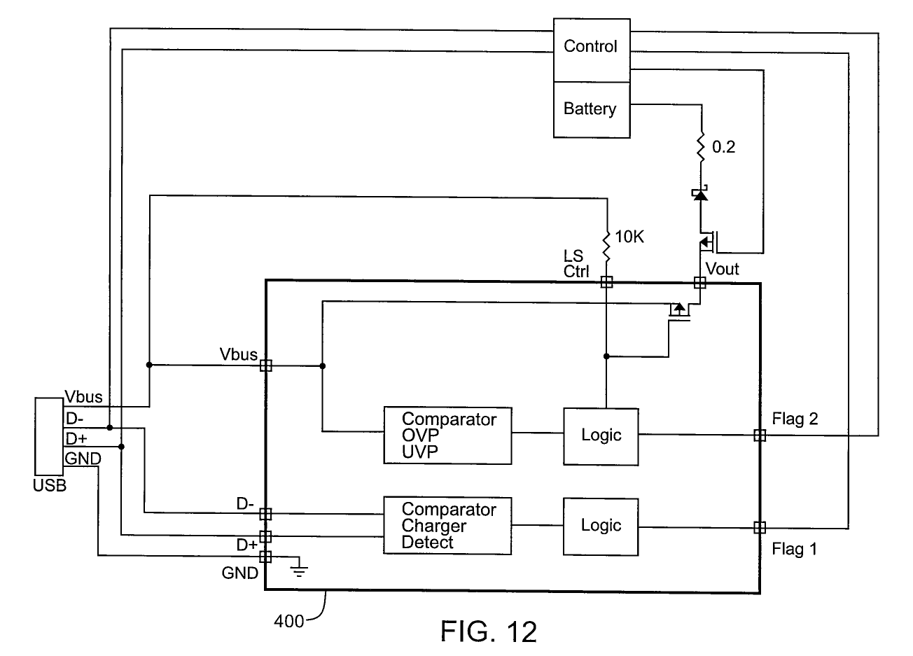

FIGS. 11(a)-11(g) show precursors that are formed during the formation of a semiconductor die package according to an embodiment of the invention.

FIG. 11(a) shows a leadframe structure 102 including a pad 102(d), a wire bonding pad 102(e), and a number of leads 102(c). The leadframe structure 102 can be obtained as described above. As shown, the pad 102(d), and a wire bonding pad 102(e) are downset with respect to the leads 102(c).

Referring to FIG. 11(b), a first semiconductor die 106 is attached to the pad 102(d) of the leadframe structure 102, using a conductive adhesive or the like.

Referring to FIG. 11(c), wires 118 including source wires 118(s) and a gate wire 118(g) are bonded to source and gate terminals in the first semiconductor die 106 and the leads 102(c). Conventional wirebonding processes can be used.

Referring to FIG. 11(d), after the wire bonding process is performed, a molding material 104 is formed over the wires 118, the first semiconductor die 106, and at least a portion of the leadframe structure 118 to form a premolded substrate 100. Suitable molding processes are described in detail above.

Referring to FIG. 11(e), after forming the premolded substrate 100, the second semiconductor die 108 is mounted to the premolded substrate 100 using an adhesive or the like.

Referring to FIG. 11(f), after the second semiconductor die 108 is mounted to the premolded substrate 100, wires 110 are bonded to the leads 102(c) of the leadframe structure 102.

Referring to FIG. 11(g), after the wirebonding process is performed, the housing material 200 is formed over the second semiconductor die 108 and the wires 110 to form the semiconductor die package 10.

FIG. 12 shows a circuit diagram that can be associated with the previously described package. The device 400 may include Vbus over-voltage protection (OVP) and D+/D− connectivity detection in a single package. The device 400 may be a USB connection monitoring device that is used to determine if a standard USB device is connected or a battery charging device is connected. In operation, the device 400 can set the Flag 1 lead to a logic high or low as an indicator to the system controller that a standard USB device or a charter is connected to the USB port. It also monitors Vbus for an over or under voltage condition. The Flag 2 lead can be set low if a condition exists where the Vbus lead is less than 3.3V or greater than 6.0V. The LS (load switch) Control (LS Ctrl) lead can be set high if a condition exists where the Vbus lead is less than 3.3V or greater than 6.0V turning off the PMOS switch.

The terminal connections in the device 400 can be as follows in an exemplary embodiment: Vbus (power connection from a charger or other external power source); D− input (USB data input); D+ input (USB data input); Gnd (device ground pin); Flag 2 (indicates if Vbus is out of voltage range (e.g., 3.3V-6V)); Flag 1 (indicates if D− and D+ are shorted; low: standard USB device; high: charger; standard output drive H=2.5V, L=0.8V).

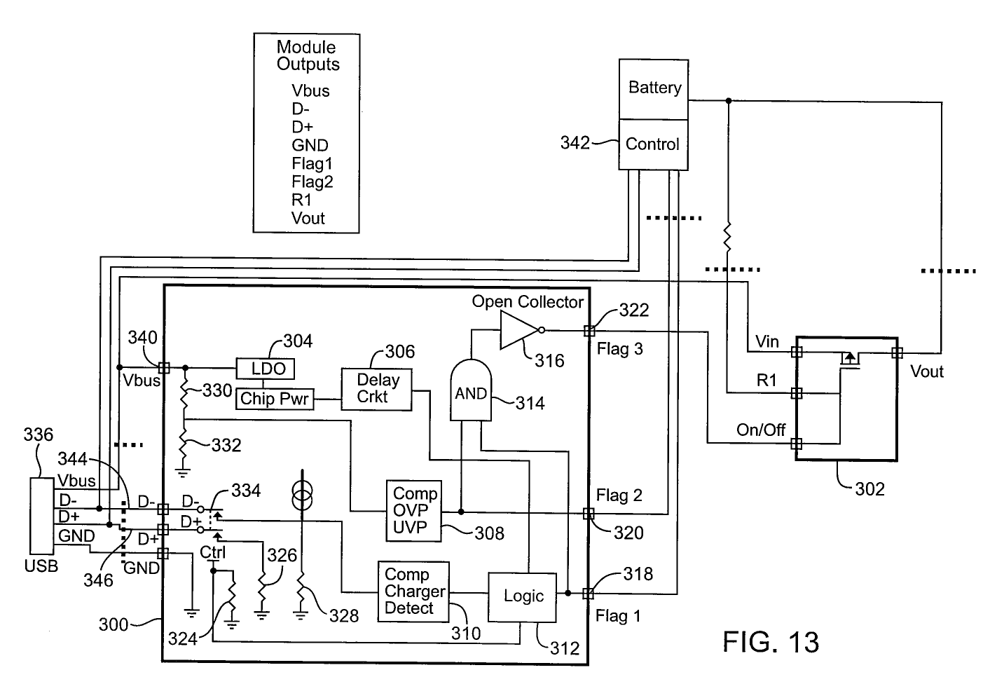

FIG. 13 shows a circuit diagram associated with the previously described package. FIG. 13 shows an integrated circuit die 300 electrically coupled to a power transistor die 302. The discrete device die 302 can be a P-channel power MOSFET die. The integrated circuit die 300 can be a USB connection monitoring device that is configured to determine if a standard USB device is connected or if a battery charging device is connected. Features of the integrated circuit die 300 may include over/under voltage detection, charger/USB device detection, and may work with a Vbus supply voltage of 2.7V to 6V. In FIG. 13, dotted lines may show where package lead connections can be provided.

Referring to FIG. 13, integrated circuit die 300 has two modes of operation. In a first mode, a charging device (not shown) is electrically coupled to USB port 336. The charging device will supply power to Vbus 340, which provides power to integrated circuit die 300. A Low Dropout Regulator (LDO) 304 regulates the voltage supplied from Vbus 340. LDO 304 provides a constant voltage to integrated circuit die 300 to protect the components of the circuit from harmful voltage fluctuation. A voltage divider comprised of resistors 330 and 332 provides a reference voltage to comparator 308. If the reference voltage is within pre-set ranges of comparator 308, then comparator 308 will set flag 2 320 high indicating that the voltage on Vbus 340 is between and inclusive of 3.3V and 6V. Flag 2 320 provides an output to the USB controller 342 indicating that PMOS device(s) can be turned on. If Flag 2 320 goes low, then the USB controller 342 turns off the PMOS device(s) because the voltage is either below 3.3V or above 6V.

The USB controller 342 also determines if there is a charging device connected to the USB port 336. A charging device connected to USB port 336 will cause a short circuit 334 between lines D- 344 and D+346. The effect of short circuit 334 is to put 200K Ohm resistors 326 and 328 in parallel, which sets the voltage at comparator 310 to 0.5V. If comparator 310 detects 0.5V, it will set Flag 1 318 high. Flag 1 318 indicates to the USB controller 342 that a charging device is connected. In order to avoid false detections of a short circuit 334 (indicating a charging device is connected to the USB port 336), a 3 ms delay is introduced. Delay circuit 306 delays the delivery of power to control logic 312 for 3 ms. This delay allows comparator 310 enough time to accurately detect whether there is a short circuit 334 between lines D− 344 and D+ 346. While control logic 312 is without power during the delay, flag 1 318 is held low keeping the PMOS devices off. After approximately 3 ms, the control logic 312 receives power and is able to set flag 1 318 according to the present conditions (either high if a short circuit 334 is present or low if no short circuit).

Flag 3 322 is used to turn on or off the power transistor die 302. The output of comparator 310 (via control logic 312) is input to And gate 314 along with the output of comparator 308. The output of And gate 314 is inverted by inverter 316, and the output of inverter 316 is flag 3 322, which drives power transistor die 302.

Again, referring to FIG. 13, in a second mode, a standard USB device is electrically coupled to USB port 336. When a standard USB device such as a headset is connected, the USB controller 342 will detect the standard USB device through lines D− 344 and D+ 346. In addition, no power will be applied to Vbus 340, so Flag 2 320 will be set low as described above. Setting Flag 2 320 low will indicate to the USB controller 342 that a non-valid Vbus 340 voltage is present, so the PMOS devices will not be turned on. Flag 1 318 will also be set low indicating a standard USB device is connected because lines D− 344 and D+ 346 will not be shorted together. Without short circuit 334 present, comparator 310 will not receive 0.5V. Instead, lines D− 344 and D+ will be connected to 15K Ohm resistor 324 to ground. Therefore, if a standard USB device is connected both comparators 308 and 310 will be set low, and Flag 3 322 will turn off power transistor die 302.

Embodiments of the invention have advantages. For example, embodiments of the invention are compact, since semiconductor dice can be stacked on each other. In addition, heat is efficiently dissipated in embodiments of the invention, since at least one of the dies in the package is exposed to the external environment. Further, embodiments of the invention can use standard flip chip technology.

The terms and expressions which have been employed herein are used as terms of description and not of limitation, and there is no intention in the use of such terms and expressions of excluding equivalents of the features shown and described, or portions thereof, it being recognized that various modifications are possible within the scope of the invention claimed. Moreover, any one or more features of any embodiment of the invention may be combined with any one or more other features of any other embodiment of the invention, without departing from the scope of the invention. For example, although a semiconductor die package with two dice is shown, other embodiments of the invention may include more than two semiconductor dice within a single semiconductor die package.

All patent applications, patents and publications noted above are herein incorporated by reference in their entirety for all purposes. None is admitted to be prior art.

What is claimed is:

1. A semiconductor die package comprising:
a premolded substrate comprising (i) a leadframe structure, (ii) a first semiconductor die comprising a first die surface and a second die surface, attached to the leadframe structure, and (iii) a molding material covering at least a portion of the leadframe structure and the first semiconductor die, wherein the premolded substrate comprises a first premolded substrate surface and a second premolded substrate surface;
a second semiconductor die stacked and attached to the second premolded substrate surface; and
a housing material on at least a portion of the second semiconductor die and the second premolded substrate surface of the premolded substrate,
wherein one of the first semiconductor die and the second semiconductor die comprises a transistor while the other comprises an integrated circuit.

2. The semiconductor die package of claim 1 wherein the first semiconductor die comprises the transistor and the second semiconductor die comprises the integrated circuit.

3. The semiconductor die package of claim 1 wherein the leadframe structure comprises leads and wherein the semiconductor die package further comprises wires coupling the second semiconductor die to the leads.

4. The semiconductor die package of claim 1 wherein the semiconductor die package further comprises solder structures coupling the first semiconductor die to the leadframe structure.

5. The semiconductor die package of claim 1 wherein the leadframe structure comprises a die attach pad and leads, wherein the leads extend away from the die attach pad.

6. The semiconductor die package of claim 1 wherein the first semiconductor die and the second semiconductor die are vertically and laterally offset from each other.

7. The semiconductor die package of claim 1 wherein the first semiconductor die comprises a vertical power MOSFET.

8. The semiconductor die package of claim 1 wherein the second semiconductor die comprises an integrated circuit die.

9. The semiconductor die package of claim 1 wherein the semiconductor die package is configured to provide over-voltage protection and USB connectivity detection.

10. The semiconductor die package of claim 1 wherein the first die surface is exposed through the molding material and is substantially coplanar with an exterior surface of the molding material.

11. A method comprising:
forming a premolded substrate comprising (i) a leadframe structure, (ii) a first semiconductor die comprising a first die surface and a second die surface, attached the leadframe structure, and (iii) a molding material covering at least a portion of the leadframe structure and the first semiconductor die, wherein the premolded substrate comprises a first premolded substrate surface and a second premolded substrate surface;
stacking and attaching a second semiconductor die on the second premolded substrate surface; and
forming a housing material on at least a portion of the second semiconductor die and the second premolded substrate surface of the premolded substrate, thereafter forming a semiconductor die package,
wherein one of the first semiconductor die and the second semiconductor die comprises a transistor while the other comprises an integrated circuit.

12. The method of claim 11 wherein the first semiconductor die comprises the transistor and the second semiconductor die comprises the integrated circuit.

13. The method of claim 11 wherein the leadframe structure comprises leads and wherein the method further comprises using wires to couple the second semiconductor die to the leads.

14. The method of claim 11 further comprising coupling the first semiconductor die to the leadframe structure using solder structures.

15. The method of claim 11 wherein the leadframe structure comprises a die attach pad and leads, wherein the leads extend away from the die attach pad.

16. The method of claim 11 wherein the first semiconductor die and the second semiconductor die are vertically and laterally offset from each other in the semiconductor die package.

17. The method of claim 11 wherein the second semiconductor die is attached to the molding material.

18. The method of claim 11 wherein the transistor comprises a power MOSFET.

19. The method of claim 11 wherein the semiconductor die package is configured to provide over-voltage protection and USB connectivity detection.

20. The method of claim 11 wherein the leadframe structure includes a die attach pad portion and wherein a surface of the die attach pad portion is exposed through the molding material.

21. The semiconductor die package of claim 1 wherein the leadframe structure includes a die attach pad portion and wherein a surface of the die attach pad portion is exposed through the molding material
